(19) United States
(12) Patent Application Publication
(10) Pub. No.: US 2013/0335156 A1
(43) Pub. Date: Dec. 19, 2013

(54) OSCILLATOR COMPRISING AN RC-CIRCUIT AND A PUSH-PULL STAGE AND ELECTRONIC DEVICE COMPRISING THE OSCILLATOR

(71) Applicants: Michael Couleur, Munchen (DE); Stefan Guenther, Freising (DE)

(72) Inventors: Michael Couleur, Munchen (DE); Stefan Guenther, Freising (DE)

(73) Assignee: TEXAS INSTRUMENTS DEUTSCHLAND GMBH, Freising (DE)

(21) Appl. No.: 13/495,875

(22) Filed: Jun. 13, 2012

(51) Int. Cl. H03K 3/26

(52) U.S. Cl. 331/111

(57) ABSTRACT

Oscillator and electronic device comprising an oscillator, wherein the oscillator has an RC-circuit and a push-pull stage. A tapping point of the RC-circuit is coupled to an input of the push-pull stage and an output of the push-pull stage is fed back to a switching transistor which is coupled to the tapping point of the RC-circuit.

### FIELD OF THE INVENTION

The invention relates to an oscillator comprising an RC-circuit coupled between a high supply voltage line and a low supply voltage line and a push-pull stage coupled to the RC-circuit. Further, the invention relates to an electronic device comprising the oscillator.

### BACKGROUND OF THE INVENTION

Oscillators are widely used; for example, for clock generation purposes in electronic devices. Fully integrated oscillators (according to the prior art) use a voltage divider combined with an RC-coupled comparator to generate the clock signal. An oscillator (according to the prior art) is shown in the simplified circuit diagram of FIG. 1. The oscillator 2 comprises an RC-circuit 4 having a resistor R and a capacitor C coupled in series between VDD and ground. A tapping point 6 between the resistor R and the capacitor C is coupled to a first input of a comparator 8. A second input of the comparator 8 is coupled to a voltage divider comprising a first resistor RB and a second resistor RT which are coupled in series between the supply voltage VDD and ground. A tapping point 10 of the voltage divider is coupled to the second input of the comparator 8. An output of the comparator 8 is coupled to a delay line 12, comprising three inverters 141, 142 and 143. The clock signal CLK is provided at the output node OUT. The clock signal CLK is fed back to a gate of a switching transistor 16. The channel of the switching transistor 16 is coupled between the tapping point 6 of the RC-circuit 4 and ground.

However, the frequency of the clock signal CLK of the oscillator 2 (according to the prior art) is limited due to the propagation delay of the comparator 8. One option to overcome this drawback is to apply cascaded comparators which however require additional circuitry. Alternatively, an LC oscillator may be applied which; however, is not fully integrated and requires larger space. Furthermore, topologies (according to the prior art) demand for additional circuitry to compensate supply influences; for example, an oscillator according to the simplified circuit diagram of FIG. 1.

### SUMMARY

It is a general object of the invention to provide an improved oscillator and an improved electronic device having an oscillator.

According to an aspect of the invention, an oscillator, comprising an RC-circuit, having a resistor and a capacitor coupled in series between a high supply voltage line and a low supply voltage line is provided. For example, the high supply voltage line may be the VDD line of an electronic device and the low supply voltage line may be a VSS line or ground. A tapping point which is located between the resistor and the capacitor of the RC-circuit is coupled to an input node of a push-pull stage. The push-pull stage comprises a first transistor and a second transistor wherein the first transistor and the second transistor are complementary transistors. For example, the first transistor and the second transistor may be matched devices wherein the complementary layout is taken from standard libraries. A channel of the first transistor and a channel of the second transistor are coupled in series between the high supply voltage line and the low supply voltage line. An output node of the push-pull stage which is located between the channel of the first transistor and the channel of the second transistor is coupled to a switching transistor which is coupled to the tapping point of the RC-circuit.

In the oscillator, according to aspect of the invention, the voltage divider and comparator (in comparison to the prior art) is replaced by the two complementary transistors which are for; example, field effect transistors (FETs). This reduces the propagation delay, and accordingly, an oscillator for providing a clock signal having a frequency of 20 MHz or higher may be provided. The oscillator is a fully integrated oscillator and there is no need for an LC-circuit or a comparator.

The channel of the first transistor and a first resistor are coupled in series between the output node of the push-pull stage and the high supply voltage line or the low supply voltage line. According to an embodiment of the invention, the channel of the first transistor and a first resistor are coupled in series, between the output node and the high supply voltage line, the channel of the second transistor and a second resistor are coupled in series between the output node of the push-pull stage, and the low supply voltage line. The ratio of the first resistor and the second resistor determines the tripping point of the inverter stage which may be coupled to the output node of the push-pull stage. An output signal of the inverter stage is coupled to the switching transistor, so as to feed back the clock signal to the switching transistor.

According to another embodiment of the invention, the first transistor is a PMOS-transistor and the source of a first transistor is coupled to the first resistor. The drain of the first transistor is coupled to the output node of the push-pull stage. Further, the second transistor is an NMOS-transistor and the source of the second transistor is coupled to the second resistor. The drain of the second transistor is coupled to the output node of the push-pull stage. The first resistor and the second resistor have equal (ohmic) resistance.

According to another embodiment, the gate of the first transistor and the gate of the second transistor of the two complementary transistors of the push-pull stage are directly connected to the tapping point of the RC-circuit. Further, the output node of the push-pull stage may be coupled to an inverter stage wherein the output of the inverter stage provides the clock signal of the oscillator. The clock signal of the oscillator may be further coupled to a gate of the switching transistor. A channel of the switching transistor is coupled between the tapping point of the RC-circuit and ground. The switching transistor is an NMOS-transistor wherein the source of the switching transistor is coupled to ground and the drain of the switching transistor is coupled to the tapping point of the RC-circuit.

According to another aspect of the invention, an electronic device, comprising an oscillator according to aspects of the invention, is provided. For example, the electronic device may be a high frequency buck converter.

Same or similar benefits, which have been already mentioned with respect to the oscillator according to aspects of the invention, pertain to the electronic device, according to aspects of the invention in a same or similar way and are therefore not repeated.

### BRIEF DESCRIPTION OF DRAWINGS

Further aspects of the invention will appear from the appending claims and from the following detailed description given with reference to the appending drawings:

FIG. 1 is a simplified circuit diagram of an oscillator, according to the prior art;

FIG. 2 is a simplified circuit diagram of an oscillator, according to an embodiment of the invention;

FIG. 3 is a simplified block diagram of an electronic device, according to an embodiment of the invention, wherein the electronic device comprises an oscillator; and

FIG. 4 is a simplified circuit diagram of a comparator according to an embodiment of the invention.

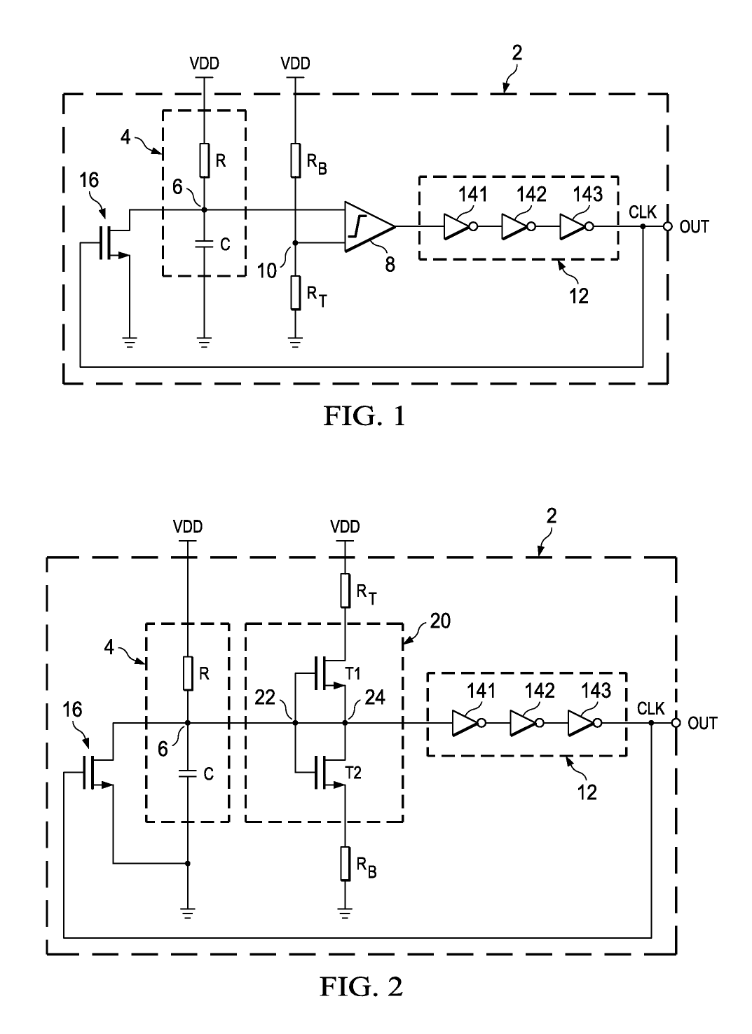

### DETAILED DESCRIPTION OF EXAMPLE EMBODIMENTS

FIG. 2 is a simplified circuit diagram of an oscillator 2 comprising an RC-circuit 4, a push-pull stage 20, an inverter stage 12 and a switching transistor 16. The RC-circuit comprises a resistor R and a capacitor C coupled in series between a high supply voltage line; for example, VDD, and a low supply voltage line, which may be coupled to ground according to the embodiment of FIG. 2. A tapping point 6, which is located between the resistor R and the capacitor C of the RC-circuit 4, is coupled to an input node 22 of the push-pull stage 20.

The push-pull stage 20 comprises a first transistor T1 and a second transistor T2, wherein the channel of the first transistor T1 and the channel of the second transistor T2 are coupled in series between the high supply voltage line (VDD) and the second supply voltage line (ground). Between the channel of the first transistor T1 and the channel of the second transistor T2, there is an output node 24 of the push-pull stage 20. The output node 24 of the push-pull stage 20 is coupled to an inverter stage 12, having three inverters 141, 142 and 143, by way of an example only. At the output of the inverter stage 12, a clock signal CLK is provided which is coupled to an output node OUT of the oscillator 2. The clock signal CLK is further coupled to the switching transistor 16. The channel of the switching transistor 16 is coupled between a tapping point 6 of the RC circuit 4 and ground.

The switching transistor 16 may be a field effect transistor (FET) and, in the embodiment illustrated in FIG. 2, the switching transistor 16 is an NMOS-transistor. The source of the switching transistor 16 is coupled to ground and the drain of the switching transistor is coupled to the tapping point 6 of the RC-circuit 4. The gate of the switching transistor 16 receives the clock signal CLK from the output of the inverter stage 12.

According to an embodiment of the invention, the first transistor T1 and the second transistor T2 are field effect transistors (FETs), wherein a complementary pair of transistors is implemented. For example, the first transistor T1 and the second transistor T2 may be matched devices (for example by using complementary standard layouts from a standard library). The first transistor T1 may be a PMOS-transistor and the second transistor T2 may be an NMOS-transistor. The gate of the first transistor T1 and the gate of the second transistor T2 may be directly coupled to the input node 22 of the push-pull stage 20. In other words, the gate of the first transistor T1 and the gate of the second transistor T2 are directly coupled to the tapping point 6 of the RC circuit 4. Further, the drain of the first transistor T1 and the drain of the second transistor T2 are directly coupled to the output node 24 of the push-pull stage 20. In other words, both, the drain of the first transistor T1 and the drain of the second transistor T2 are directly coupled to the inverter stage 12. The push-pull stage 20 further comprises a first resistor RT and a second resistor RB. The first resistor RT and the channel of the first transistor T1 are coupled in series between the output node 24 of the push-pull stage 20 and the high supply voltage line VDD. The second resistor RB and the channel of the second transistor T2 are coupled in series between the output node 24 of the push-pull stage 20 and the low supply voltage line. By way of an example only, low supply voltage line is coupled to ground. In other words, the source of the PMOS-transistor, which is the first transistor T1, is directly coupled to the first resistor RT. The source of the NMOS-transistor, which is the second transistor T2, is directly coupled to the second resistor RB.

The ratio between the ohmic resistance of the two resistors RT and RB determines the tripping point of the inverter stage 12. The tripping voltage V_TRIP may be determined using the following formula:

V_TRIP=(RB)/(R_{—}B+R_{—}T).

R_B is the ohmic resistance of the first resistor RB. In other words, R_B is the resistance between the source terminal of the NMOS-transistor (second transistor T2) and the low supply voltage line which may be VSS or ground. R_T is the ohmic resistance of the second resistor RT. In other words, R_T is the resistance between the source terminal of the PMOS-transistor (first transistor T1) and the first supply voltage line which may be VDD.

The tripping point may be set to the middle of the supply voltage range by choosing resistors having equal ohmic resistance which means: R_B =to R_T. The oscillator's frequency may be calculated by help of the following formula:

f=1/(RC*In((R_{—}B+R_{—}T)/R_{—}B))=1/(RC*In(2))

For practical implementation, additional driver stages may be added to the oscillator 2 in the simplified circuit diagram of FIG. 2. However, the propagation delay of driver stages is relatively small and consequently, the frequency dominating parameter will be still given by the RC-circuit 4.

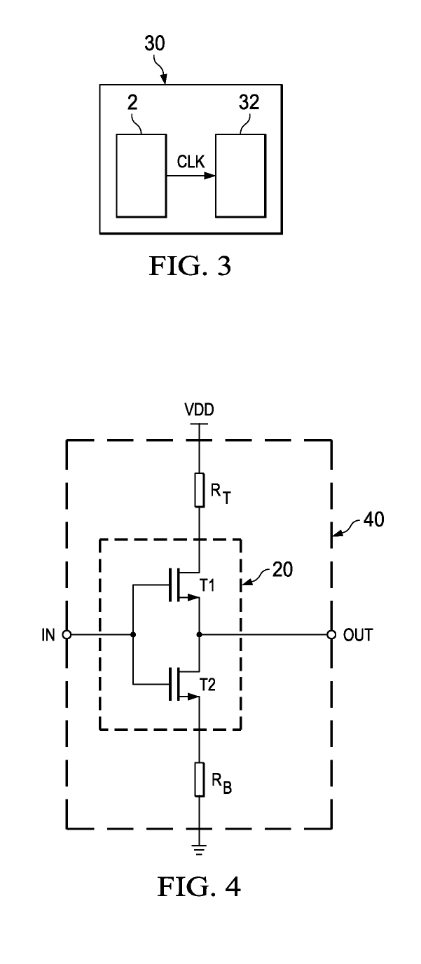

The oscillator 2, according to embodiments of the invention, may be implemented in an electronic device 30 which is preferably a 20 MHz buck converter. A simplified block diagram of the electronic device 30 is shown in FIG. 3. The oscillator 2 provides a clock signal CLK to the converter stage 32, (for example a converter stage of a buck converter). The oscillator 2 is a fully integrated device and may be implemented in electronic devices 30, having a need for high frequency clock generation.

In FIG. 4, there is a simplified circuit diagram of a comparator 40, according to an embodiment of the invention. The comparator 40 comprises a push-pull stage 20 having a first resistor RT and a second resistor RB. The first resistor RT and the channel of the first transistor T1 are coupled in series between and output node OUT of the comparator 40 and the high supply voltage 5 line VDD. The second resistor RB and the channel of the second transistor T2 are coupled in series between the output node OUT and the low supply voltage line. By way of an example only, the low supply voltage line is coupled to ground. If field effect transistors are applied for manufacturing the comparator 40, the first transistor T1 may be a PMOS-transistor. The channel of this PMOS-transistor (in FIG. 4 the source of the PMOS-transistor T2) is directly coupled to the first resistor RT. The second transistor T2 may be an NMOS transistor and the channel of this transistor (in the embodiment of FIG. 4, a source of the NMOS-transistor) is directly coupled to the second resistor RB. The gate of the first transistor T1 and the gate of the 15 second transistor T2 are both coupled to an input node IN of the comparator 40.

A reference voltage within the comparator 40 is provided by a ratio between the values for the (ohmic) resistance of the first resistor RT and the second resistor RB. The first and/or second resistor RT, RB may have a predetermined or adjustable (ohmic) value, the latter requires implementation of a variable resistor (not shown). The ratio between the values of the (ohmic) resistance of first and second resistor RT, RB determines a tripping point of the comparator 40. The “reference voltage” depends on the supply voltage VDD and consequently, a supply dependent comparator 40 may be provided. The transistors T1, T2 of the comparator 40 are configured in that their on-resistance is significantly lower than the resistance of the first and/or second resistor RT, RB. A ratio between the value of the resistance of the first and/or second resistor RT, RB and the value of the on-resistance of the first and/or second transistor T1, T2 is higher than 100. The ratio is equal to 100, 200, 250, 500, 750 or 1000. Further, the first resistor RT and the second resistor TB have equal (ohmic) resistance. The settling time of the comparator shown in FIG. 4 is very short as no bias currents are needed.

Although the invention has been described in detail, it should be understood that various changes, substitutions and alterations, may be made thereto without departing from the spirit or scope of the invention as defined by the appended claims.

1. An oscillator comprising:
an RC-circuit having a resistor and a capacitor coupled in series between a high supply voltage line and a low supply voltage line, a tapping point between the resistor and the capacitor of the RC-circuit being coupled to an input node of a push-pull stage comprising:
a first transistor and a second transistor;
wherein the first transistor and the second transistor are complementary transistors and a channel of the first transistor and a channel of the second transistor are coupled in series between the high supply voltage line and the low supply voltage line; and
an output node between the channel of the first transistor and the channel of the second transistor of the push pull stage being coupled to a switching transistor which is coupled to the tapping point of the RC-circuit.

2. The oscillator according to claim 1, wherein the channel of the first transistor and a first resistor are coupled in series between the output node of the push pull stage and the high supply voltage line or low supply voltage line.

3. The oscillator according to claim 1, wherein the channel of the first transistor and a first resistor are coupled in series between the output node of the push pull stage and the high supply voltage line and the channel of the second transistor and a second resistor are coupled in series between the output node of the push pull stage and the low supply voltage line.

4. The oscillator according to claim 3, wherein the first transistor is a PMOS transistor and the source of the first transistor is coupled to the first resistor and the drain of the first transistor is coupled to the output node of the push-pull stage and wherein the second transistor is an NMOS transistor and the source of the second transistor is coupled to the second resistor and the drain of the second transistor is coupled to the output node of the push-pull stage.

5. The oscillator according to claim 3, wherein the first resistor and the second resistor have equal resistance.

6. The oscillator according to claim 1, wherein the gate of the first transistor and the gate of the second transistor are directly connected to the tapping point of the RC-circuit.

7. The oscillator according to claim 4, wherein the switching transistor is an NMOS transistor.

8. The oscillator according to claim 1, wherein the trip point of the push-pull stage may be determined by:
V_TRIP=(RB)/(R_{—}B+R_{—}T)

9. The oscillator of claim 1, wherein the frequency of oscillation may be determined by resistance of first and second resistor RT, RB determines a tripping point of the comparator 40.

10. The oscillator of claim 8, wherein the frequency of oscillation may be determined by:
f=1/(RC*In ((R_{—}B+R_{—}T)/R_{—}B))=1/(RC*In(2))

11. An electronic device comprising an oscillator according to claim 1.

12. A method of generating clock pulses comprising:
coupling a push-pull stage to a tap between a resistance and a capacitance;
coupling an output of the push-pull stage to an inverter;
coupling an output of the inverter to a switching transistor coupled between the tap and a reference voltage.

13. The method according to claim 12, wherein the push-pull stage comprises first and second transistors and wherein the first transistor and the second transistor are complementary transistors and a channel of the first transistor and a channel of the second transistor are coupled in series between the high supply voltage line and the low supply voltage line.

14. The method according to claim 13, wherein a channel of the first transistor and a first resistor are coupled in series between the output node of the push pull stage and the high supply voltage line or low supply voltage line.

15. The method according to claim 1, wherein the channel of the first transistor and a first resistor are coupled in series between the output node of the push pull stage and the high supply voltage line and the channel of the second transistor and a second resistor are coupled in series between the output node of the push pull stage and the low supply voltage line.

16. The method according to claim 15, wherein the first transistor is a PMOS transistor and the source of the first transistor is coupled to the first resistor and the drain of the first transistor is coupled to the output node of the push-pull stage and wherein the second transistor is an NMOS transistor and the source of the second transistor is coupled to the second resistor and the drain of the second transistor is coupled to the output node of the push-pull stage.

17. The method according to claim 15, wherein the first resistor and the second resistor have equal resistance.

18. The method according to claim 12, wherein a gate of the first transistor and a gate of the second transistor are directly connected to the tapping point of the RC-circuit.

19. A buck regulator having a clock generating comprising:
an RC-circuit having a resistor and a capacitor coupled in series between a high supply voltage line and a low supply voltage line, a tapping point between the resistor and the capacitor of the RC-circuit being coupled to an input node of a push-pull stage comprising:
a first transistor and a second transistor;
wherein the first transistor and the second transistor are complementary transistors and a channel of the first transistor and a channel of the second transistor are coupled in series between the high supply voltage line and the low supply voltage line; and
an output node between the channel of the first transistor and the channel of the second transistor of the push pull stage being coupled to a switching transistor which is coupled to the tapping point of the RC-circuit.
